(19) United States
(12) Patent Application Publication
(10) Pub. No.: US 2009/0267179 A1
(43) Pub. Date: Oct. 29, 2009

(54) SYSTEM FOR POWER PERFORMANCE OPTIMIZATION OF MULTICORE PROCESSOR CHIP

(75) Inventors: Subramanian S. Iyer, Mount Kisco, NY (US); Babar Ali Khan, Ossining, NY (US); Chandrasekharan Kothandaraman, Hopewell Junction, NY (US); Norman Whitelaw Robson, Hopewell Junction, NY (US)

Correspondence Address: ZILKA-KOTAB, PC- IBMS, P.O. BOX 721120, SAN JOSE, CA, 95172-1120, US

(73) Assignee: International Business Machines Corporation, Armonk, NY (US)

(21) Appl. No.: 12/108,905

(22) Filed: Apr. 24, 2008

(51) Int. Cl. H01L 23/525

(52) U.S. Cl. 257/529; 257/E23.149

(57) ABSTRACT

A system in one embodiment includes a multiprocessor chip comprising a plurality of cores; a plurality of power circuits, each power circuit being coupled to one of the cores; and an electrically programmable fuse in each power circuit. Each electrically programmable fuse further comprises a first electrode coupled to the associated power circuit; a second electrode coupled to the associated power circuit; a first pad coupled to the first electrode; a second pad coupled to the second electrode; and an electrically conductive material extending between the first and second electrodes and forming part of the associated power circuit, the electrically conductive material being characterized as tending to electromigrate from one of the electrodes to the other electrode under an applied electrical current passing between the electrodes, wherein the electromigration increases an overall resistance of the power circuit.

### BACKGROUND OF THE INVENTION

The present invention relates to multicore processor units, and more particularly, this invention relates to programmable on-chip fuses for multicore processor units.

Multiprocessor chip yields are limited by the power-performance characteristics of the component processors. One leaky processor core could make the entire multicore chip inoperable. As the number of cores included in the multicore processor is increased, this risk of having a leaky core also increases.

Currently, multicore processors are not bonded out at the C4-level. In a typical application, after testing, the undesirable processors are identified. Custom masks are then used to disconnect the processors which do not meet minimum specifications at the C4 level. The current manufacturing process for multicore processors can not account for all possible combinations of faulty processors (as it is currently performed at the 8-processor level, and only for a subset of all possible combinations) and adds to the infrastructural costs. Furthermore, the current multicore processor design for dealing with faulty chips is not scaleable for a larger number of processors.

### SUMMARY OF THE INVENTION

A system in one embodiment includes a multiprocessor chip comprising a plurality of cores; a plurality of power circuits, each power circuit being coupled to one of the cores; and an electrically programmable fuse in each power circuit. Each electrically programmable fuse further comprises a first electrode coupled to the associated power circuit; a second electrode coupled to the associated power circuit; a first pad coupled to the first electrode; a second pad coupled to the second electrode; and an electrically conductive material extending between the first and second electrodes and forming part of the associated power circuit, the electrically conductive material being characterized as tending to electromigrate from one of the electrodes to the other electrode under an applied electrical current passing between the electrodes, wherein the electromigration increases an overall resistance of the power circuit.

Any of these embodiments may be implemented in a logic function, program or software.

Other aspects, advantages and embodiments of the present invention will become apparent from the following detailed description, which, when taken in conjunction with the drawings, illustrate by way of example the principles of the invention.

### BRIEF DESCRIPTION OF THE DRAWINGS

FIG. 1 is a schematic diagram of a multicore processor with programmable fuse elements according to one embodiment.

FIG. 2 is a schematic diagram of a programmable fuse element according to one embodiment,

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treaties, etc.

It must also be noted that, as used in the specification and the appended claims, the singular forms “a,” “an” and “the” include plural referents unless otherwise specified.

The following description discloses several preferred embodiments of systems capable of disconnecting one or more cores, also referred to as multiprocessor units (MPUs), of a multiprocessor chip from a power bus after module build has been completed.

In one general embodiment, a system comprises a multiprocessor chip which comprises a plurality of cores; a plurality of power circuits, each power circuit being coupled to one of the cores; an electrically programmable fuse in each power circuit, each electrically programmable fuse further comprising: a first electrode coupled to the associated power circuit; a second electrode coupled to the associated power circuit; a first pad coupled to the first electrode; a second pad coupled to the second electrode; an electrically conductive material extending between the first and second electrodes and forming part of the associated power circuit, the electrically conductive material being characterized as tending to electromigrate from one of the electrodes to the other electrode under an applied electrical current passing between the electrodes, wherein the electromigration increases an overall resistance of the power circuit.

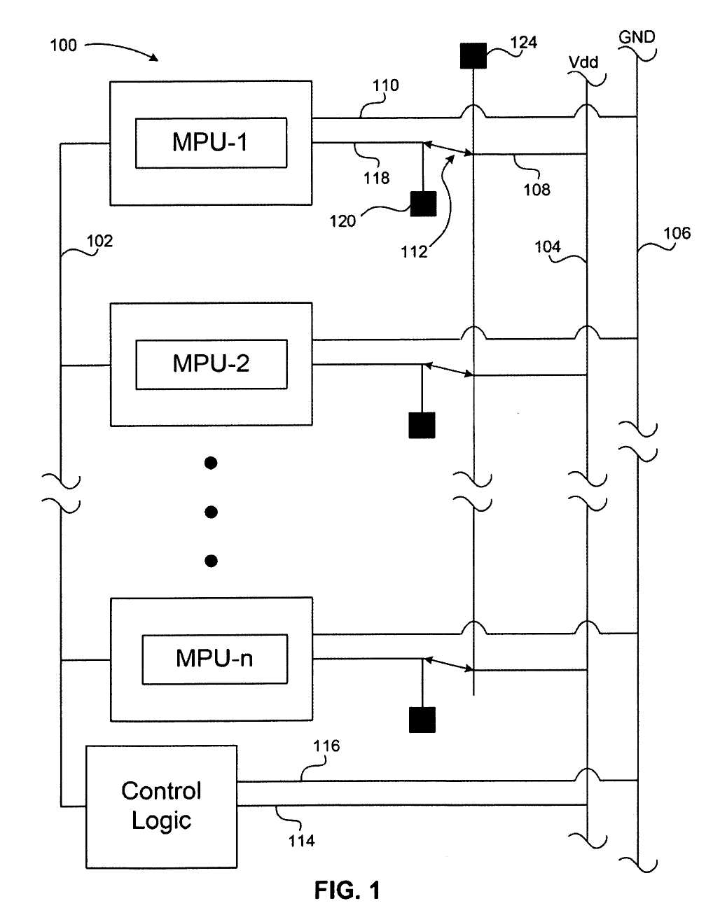

FIG. 1 is a schematic diagram of a multicore processor 100 with programmable fuse elements according to one embodiment. The control bus 102 connects the Control Logic with each of the multicore processor units (MPUs). The Control Logic is also connected to the power bus (combination of the Vdd 104 and ground 106) through connections 114 and 116. Similarly, each of the MPUs (MPU-1, MPU-2, . . . , MPU-n) are connected to the power bus through individual connections to the Vdd 104 and ground 106.

As an example, MPU-1 is connected to the power bus through connection 108 to the Vdd 104 and through connection 110 to the ground 106. On connection 108, there is a programmable fuse 112 which can be disconnected, causing MPU-1 to no longer be connected to the power bus. There is a programmable fuse for each MPU (MPU-1, MPU-2, . . . , MPU-n) that can be disconnected separately to remove power from each of the MPUs individually. For example, to disconnect MPU-1 from the power bus, a fusing current is passed through dedicated electrical pads 120 and 124 so that the programmable fuse 112 becomes disconnected. The power circuit 118 for MPU-1 is then isolated from the power bus. This process can be repeated for each faulty MPU in the multicore processor 100.

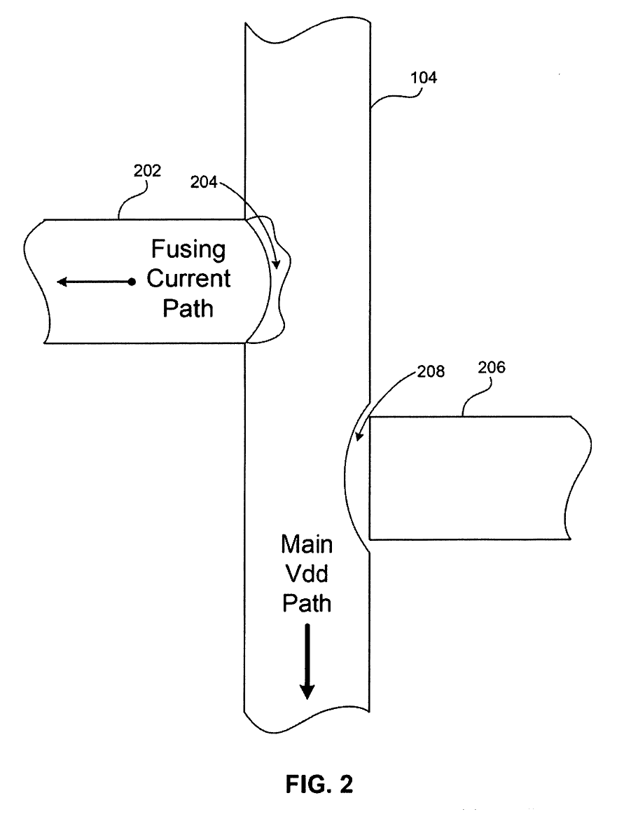

FIG. 2 is a schematic diagram of a programmable fuse element according to one embodiment. The Main Vdd Path 104 has two connections in this view, a Fusing Current Path 202 and a non-desired connection 206. Each power circuit will have an additional electrical pad to drive a fusing current through the final level metal wire. The junctions between the wires and the Main Vdd Path 210 will be selectively either voided 208 or accumulated 204 with metal due to the effect of electromigration.

This electromigration effect will increase the resistance of the Main Vdd Path 210, and hence will decrease leakage from the chip. Also, complete depletion of the metal between the Main Vdd Path 210 and the non-desired connection 206 is not necessary to decrease the leakage from a defective MPU.

The advantages of using a multicore processor with programmable fuses are many. First, traditional laser fuse approaches require an additional header or footer device (which in turn drops the Vdd and/or increases the silicon area required). Second, Powerfuse (using a laser to program the metal wire) causes reliability failures. The manufacturing yield of multicore processors with programmable fuses will be significantly higher than any existing solutions. Also, the present system has few additional costs, including not requiring any additional equipment since the fuses can be programmed using existing test equipment. Finally, there are no significant increases in silicon area required as only wiring and C4 pad levels may be used in the present system, without use of the silicon area.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

1. A system, comprising:
a multicore multiprocessor chip comprising a plurality of cores;
a plurality of power circuits, each power circuit being coupled to one of the cores;
an electrically programmable fuse in each power circuit, each electrically programmable fuse further comprising:
a first electrode coupled to the associated power circuit;
a second electrode coupled to the associated power circuit;
a first pad coupled to the first electrode;
a second pad coupled to the second electrode; and
an electrically conductive material extending between the first and second electrodes and forming part of the associated power circuit,
the electrically conductive material being characterized as tending to electromigrate from one of the electrodes to the other electrode under an applied electrical current passing between the electrodes,
wherein the electromigration increases an overall resistance of the power circuit.
